(19) United States
(12) Patent Application Publication
(10) Pub. No.: US 2012/0167955 A1
(43) Pub. Date: Jul. 5, 2012

(54) Solar panels with clear encapsulant layer

(76) Inventors: Robert F. Davis, Wilmington, DE (US); E. David Santoleri, Glen Mills, PA (US)

(21) Appl. No.: 12/807,423

(22) Filed: Sep. 2, 2010

(51) Int. Cl. H01L 31/048

(52) U.S. Cl. 136/251

(57) ABSTRACT

Solar panels of ethylene-vinyl acetate copolymer resin having at least one layer of substantially clear encapsulant and a second layer of laminar encapsulant having a substantially clear layer and a pigmented layer provide excellent long term performance.

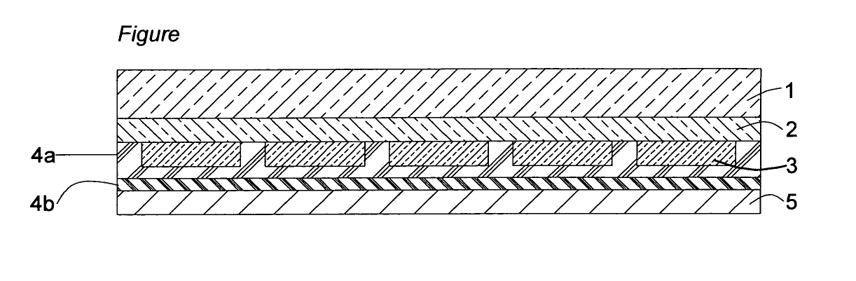

### BACKGROUND OF THE INVENTION

The present invention relates to solar panels characterized by improved efficiency in the generation of power and excellent long-term service.

It is well known that a white ethylene vinyl acetate (EVA) copolymer layer of a backsheet facing the front of a photovoltaic (PV) panel will reflect photons that miss the cells. It is also recognized that less power production will be realized with each additional layer through which the incident light must pass. Some of these photons will reflect back to the underside of the glass in the panel and bounce back to the cell where they will then penetrate the cell, thereby liberating electrons. However, after several years of exposure, the backsheet mid layer of polyethylene terephthalate (PET) polyester film will turn yellow and brown. This color will show through the white EVA layer if that layer is insufficiently opaque. This will reduce the level of reflectivity and result in less power being generated.

Previous attempts to solve this problem included increasing the pigment loading of the single layer EVA in the backsheet. However, this results in increased defects in the extruded sheet. Specifically, particle agglomeration on the surface will increase in frequency, resulting in a defective backsheet and possible breakage of the PV cells during lamination.

### SUMMARY OF THE INVENTION

The present invention provides an improved solar panel that solves the long-standing problems noted above, and exhibits excellent long term durability.

Specifically, the present invention provides a solar panel comprising a front cover, a first layer of substantially clear encapsulant, a plurality of solar cells, and a second layer of encapsulant, the second layer of encapsulant comprising a substantially clear layer and a pigmented layer, the pigmented layer being contiguous to a backing sheet.

### BRIEF DESCRIPTION OF THE DRAWING

The FIGURE is a schematic, cross-sectional illustration of a solar panel of the present invention.

### DETAILED DESCRIPTION OF THE INVENTION

As illustrated in the FIGURE, the present invention relates to solar panels comprising a front cover 1, a first layer of substantially clear encapsulant 2, a plurality of solar cells 3, a second layer of encapsulant 4, and a backing sheet 5 adjacent to the encapsulant. The second layer of encapsulant comprises substantially clear portion 4a and pigmented portion 4b. Constructions of this type are generally described, for example, in Hanoka, U.S. Pat. Nos. 5,620,904, 6,353,042 and 6,187,448, each hereby incorporated by reference.

The front cover is typically glass, but can also be polymeric film such as ethylene tetrafluoro ethylene (ETFE).

In accordance with the present invention, the solar panels comprise a first layer of substantially clear encapsulant. By substantially clear is meant that this layer will transmit at least about 90% of incident light. The materials used for both layers of encapsulant can vary widely, and can include, for example, ethylene vinyl acetate, ionomer, polyvinyl butyral, polyolefins and modified polyolefins, and silicones.

The solar cells used in the present invention can be selected form a wide variety of crystalline silicon (c-Si) cells typically used in the art, including, for example, those commercially available from SunPower, QCells, Motech, and Evergeen Solar.

In accordance with the present invention, a second layer of encapsulant is provided, comprising a substantially clear layer, as defined above, and a pigmented layer. The total thickness of this second layer of encapsulant is generally about 450μ, typically divided between the pigmented and clear portions at 150μ and 300μ respectively. The pigmented layer is contiguous to the backing sheet. In these constructions the pigmented layer is generally about from 75μ to 200μ in thickness, and preferably about from 125μ to 175μ.

The second layer of encapsulant is selected from the same materials as the first layer of encapsulant, and is preferably the same material as the first layer of encapsulant. Particularly preferred are encapsulant layers which consist essentially of at least one olefinic polymer selected from ethylene vinyl acetate and low density polyethylene. It is also preferred that the pigmented portion comprises about from 5 to 10% by weight opacifying pigment, and especially about 8% by weight of opacifying pigment. Such structures have been found to provide particularly satisfactory performance in photovoltaic panels. The particular opacifying pigment used can vary widely, but is preferably selected from at least one of TiO₂, and BaSO₄.

It is also preferred that at least the clear portion in the laminar structure further comprises at least one ultraviolet light absorber. The particular ultraviolet light absorber can also vary widely, but is preferably selected from at least one of benzophenone, benzotriazole, and hindered amines. These UV absorbers can also be included in the pigmented portion of the encapsulant layer.

The EVA used can contain about from 25% to 33% vinyl-acetate, and preferably about from 28% to 32%. EVA encapsulants also generally contain cross-linking initiators such as peroxides and antioxidants such as that commercially available as Irganox.

The solar panels prepared according to the present invention provide improved power generation and excellent power retention characteristics over extended periods of time. The constructions of the present invention result in higher reflectivity, both initially and after long term exposure. By pigmenting the latter portion of the second encapsulant layer, photons that pass between cells will be more likely to reflect back to the underside of the front cover and then bounce back onto the cells. There will accordingly be less distance that the photons will need to travel. Also, the reason why the entire second layer of encapsulant is not pigmented is the likelihood that pigmented encapsulant will settle on the front side of the cells during the panel lamination step when the encapsulant melts and flows prior to gelling. This will reduce the power output of the cells by reducing the surface area of the cells where photons can penetrate. The constructions of the present invention are expected to exhibit excellent durability to degradation in outdoor conditions and retain their original color for extended periods.

The present invention is further illustrated by the following specific Example and Comparative Example.

### EXAMPLE and COMPARATIVE EXAMPLE

A photovoltaic solar panel was prepared comprising a sheet of glass, a layer of 450 micron substantially clear ethylene/vinyl acetate (EVA) encapsulant, photovoltaic solar cells strung together in series, a second layer of 450 micron EVA encapsulant and a backsheet. The second layer of encapsulant comprised substantially ⅔ of clear and ⅓ pigmented EVA. The EVA had a VA content of 28% and the pigmented portion contained 6% TiO₂. Both encapsulant layers contained UV absorbers, cross-linking initiators and antioxidants typically found in encapsulant compositions. A commercially available backsheet was used consisting of polyvinyl fluoride, polyethylene terephthalate and EVA(TPE).

The panel was laminated in a vacuum laminator for 15 minutes and removed hot. The laminating cycle consisted of 6 minutes of evacuation at 5 torrs, 1 minute of bladder deployment to one atmosphere and 8 minutes of press time. The laminator maintained a constant temperature of 150 degrees Celsius.

The laminate was exposed to a temperature of 85 degrees Celsius and 85% relative humidity for 2,000 hours. In Comparative Example A, another PV solar panel was prepared according to the same procedure, except the second layer of encapsulant was substantially clear. The backsheet was the same as that used in the Example. The two panels were then tested, and measured for power output. The panel of the Example yielded about 3% more power than the panel of Comparative Example A.

We claim:

1. A solar panel comprising a front cover, a first layer of substantially clear encapsulant, a plurality of solar cells, and a second layer of encapsulant, the second layer of encapsulant comprising a substantially clear layer and a pigmented layer, the pigmented layer being contiguous to a backing sheet.

2. A solar panel of claim 1 wherein the opacifying pigment is selected from at least one of TiO₂, and BaSO₄.

3. A solar panel of claim 2 wherein the opacifying pigment comprises about from 2 to 10 weight % of the pigmented portion of the second layer ofs encapsulant.

4. A solar panel of claim 2 wherein the opacifying pigment comprises about from 4 to 7 weight % of the pigmented portion of the second layer of encapsulant.

5. A solar panel of claim 1 wherein each layer of encapsulant further comprises at least one ultraviolet light absorber.

6. A solar panel of claim 5 wherein the ultraviolet light absorber is selected from at least one of benzophenone, benzotriazole, and hindered amines.

7. A solar panel of claim 1 wherein the pigmented portion of the second layer of encapsulant is about from 75μ to 200μ in thickness.

8. A solar panel of claim 7 wherein the pigmented portion of the second layer of encapsulant is about from 125μ to 175μ in thickness.
